(19) United States
(12) Patent Application Publication
(10) Pub. No.: US 2003/0102572 A1
(43) Pub. Date: Jun. 5, 2003

(54) Integrated assembly protocol

(76) Inventors: Richard J. Nathan, Morgan Hill, CA (US); William H. Shepherd, Placitas, NM (US)

Correspondence Address: SKJERVEN MORRILL LLP, 25 METRO DRIVE, SUITE 700, SAN JOSE, CA, 95110, US

(21) Appl. No.: 09/953,005

(22) Filed: Sep. 13, 2001

(51) Int. Cl. H01L 23/48; H01L 23/52; H01L 29/40

(52) U.S. Cl. 257/780

(57) ABSTRACT

A monolithic integrated structure including one or more packaged components such as integrated circuits, discreet components, LED's, photocouplers and the like is formed by placing electrically conductive lands on one surface of each packaged component, and then placing one or more packaged components into a substrate such that the surface of each packaged component containing the electrically conductive lands is visible and substantially coplanar with the top surface of the substrate. An electrically conductive layer is then formed over the top surface of the substrate, on the visible surfaces of each of the packaged components and on the electrically conductive lands contained thereon. The electrically conductive layer is then patterned using standard photolithographic techniques known in the semiconductor and printed circuit processing arts to form an electrical interconnect which connects the packaged components into a desired electrical circuit. The resulting structure thus is low cost yielding either packaged single integrated circuit structures or multi-package structures which either form an electronic system or which are capable of being electrically interconnected with other such structures to form an entire electronic system.

### FIELD OF INVENTION

This invention relates to substrates, including but not limited to printed circuit boards, which carry at least one packaged component (such as an integrated circuit chip, or a discrete element such as a resistor, capacitor, inductor, transistor, LED, optical device, MEMS or photocoupler, for example) and in particular to a substrate for receipt of one or more packaged components face down or face up, in such a manner as to allow the interconnection of the packaged components using photolithographic techniques so as to provide a monolithic integrated structure combining the component packages and the substrate.

### BACKGROUND OF THE INVENTION

Substrates such as printed circuit boards are well known. Typically, printed circuit boards incorporate one or more levels of conductive traces to interconnect packaged integrated circuit chips or other electronic components carried by the board to form a system capable of carrying out a selected function or functions. Typically, one or more packaged components shown in FIG. 1 as packaged integrated circuit 11-1, are attached to the printed circuit board by placing each packaged component onto the printed circuit board such that solder balls shown as 12-1 through 12-N in FIG. 1, or conductive leads on the component packages are aligned with and physically connected to electrical contacts formed on or as part of the printed circuit board 13. If the printed circuit board 13 contains vias lined with copper or other conductive material or electrical contacts coated with conductive material, such as solder paste, then the packaged components to be connected to the printed circuit board 13 would typically have leads or conductive balls, respectively, extending therefrom, such that the leads or conductive balls can be placed into or onto corresponding vias or contacts respectively, on the printed circuit 13 board and soldered thereto. If the components are packaged in ball grid array packages with solder balls or similar structures on a surface of each package, then each packaged component is placed, solder balls or similar structure down, on the printed circuit board such that the solder balls or similar structures on the package align properly with conductive contacts formed on the printed circuit board.

Typically, the solder balls associated with the packages contain lead. Lead creates environmental hazards. Accordingly, one goal of the electronics industry is to eliminate the lead from the conductive solders, solder paste, solder bumps and balls used with component packages and substrates such as printed circuit boards.

### SUMMARY OF THE INVENTION

In accordance with this invention, a substrate such as a printed circuit board, is provided which allows a component package to be implemented without conductive leads or conductive balls and yet still be connected to to-be-formed electrically conductive traces or pads on the substrate.

In accordance with one embodiment of this invention, a component package is formed with electrically conductive lands and/or pads on one surface of the package. The component package is then mounted in a cavity formed in a substrate with the package top adhered physically to the bottom surface of the cavity, such that the lands on the bottom surface of the package face outward from the substrate. In the preferred embodiment, the package lands are located in substantially the same plane as the top surface of the substrate. An electrically conductive material is then formed over the top surface of the substrate and over the exposed surface and lands of the component package. Photolithographic techniques of the type well-known in the printed circuit board manufacturing arts are then used to mask and pattern the conductive layer by removing unwanted conductive material to configure the conductive layer into electrically conductive leads extending from the lands on the component package over the top surface of the substrate. In this embodiment and in the other embodiments of this invention, the tolerance allowed with respect to the relative location of the package lands vis-à-vis the location of the top surface of the substrate will be determined by the resolution and depth of field of the photolithographic equipment used in processing the structure in accordance with this invention to form the conductive leads or traces over the lands on the packaged component and the top surface of the substrate. The term “conductive” will be used in this specification to mean “electrically conductive,” unless otherwise stated. The term “lands” and the term “pads” will mean “electrically conductive lands” or “electrically conductive pads” even though one or both of the modifying words “electrically conductive” are omitted.

In another embodiment of this invention, more than one packaged component will be placed in cavities formed in a substrate such that conductive lands formed on the exposed surfaces of the packages are visible and in substantially the same plane as the top surface of the substrate. Well-known techniques are then used to deposit a layer of conductive material onto the exposed surface of the substrate and onto the land-containing exposed surfaces of the packaged components and to pattern the conductive material to form conductive leads running over the lands on the packaged components and over the top surface of the substrate. By appropriately patterning the conductive layer, selected conductive lands or pads on each packaged component are electrically connected with the appropriate lands or pads on other packaged components similarly mounted on the substrate and/or with lands or pads on the substrate connected to traces on the substrate to form a desired electrical circuit or system or portion thereof. Certain of these traces will usually be connected directly to input/output pins or leads on the substrate which allow the substrate to be electrically connected to other substrates or as part of a larger system.

In accordance with still another embodiment of this invention, the substrate containing the packaged components will itself have multiple layers of traces to which contact is made using vias formed in a well-known manner in the substrate. The vias thereby facilitate the interconnection of the packaged components to form more complex electronic systems.

In still another embodiment of this invention, the substrate will be formed of a material which softens when heated. The packaged components will then be pressed into the heated substrate to allow each packaged component to sink into and be surrounded by the material of the substrate such that the conductive land-containing surface of each packaged component essentially will remain visible but the remainder of each packaged component will be firmly surrounded and adherently held in the substrate by the substrate material when this material re-hardens upon cooling. The structure is then further processed by depositing a layer of conductive material over the top surface of the substrate and over the exposed land-containing surfaces of the packaged components. Photolithographic techniques of a type well known in the manufacture of printed circuit boards are then used to form conductive traces over the land-containing surfaces of the packaged components and the substantially co-planar substrate surface. When the substrate contains multi-layer traces, the interconnect pattern formed on the top surface of the substrate is arranged to interconnect selected traces of the multiple layers as well as the packaged components to form the desired electrical circuit. Typically, the traces are accessed by vias, or by conductive contacts which are formed on the top surface of the substrate and connected by conductive material in the vias to the underlying traces.

In an alternative embodiment of this invention, one or more packaged components are placed in one or more cavities on the substrate with the conductive lands or pads facing down to the bottom of the cavity. An additional layer of support material is then formed over the top surface of the substrate and the packaged components residing in the cavities. The structure is then flipped over such that what previously was the bottom of the structure becomes the top. Material is removed from the now top of the substrate until the lands or pads on the packaged components contained in the cavities are exposed. At this point, the electrically conductive lands or pads on the packaged components are in a plane which is substantially coplanar with the newly formed top surface of the substrate exposed by the removal of the material. Electrically conductive material is then formed over the exposed surfaces of the packages, over the lands on these exposed surfaces and over the newly exposed substrate surface. A photolithographic process is then employed to provide electrically conductive traces selectively interconnecting the exposed lands or pads on the packaged components so as to form a desired circuit or system.

In an additional embodiment of this invention, the substrate comprises a printed circuit board which contains multiple layers of traces. In this embodiment, the printed circuit board may itself contain lands or pads on the top surface thereof to allow the traces in the multiple layers to be electrically interconnected with the packaged components placed in cavities on the printed circuit board.

In another embodiment of this invention, a substrate is made with cavities having sides possessing fixed angles from the vertical so as to appear trapezoidal from a side view. The substrate may be manufactured using a stainless steel or plastic mold or a mold made from any other suitable material that is custom created for each electronic system to be incorporated in the substrate. The mold can, for example, be used to stamp, inject, spin cast or otherwise form the substrate. Typically, the systems to be fabricated using the substrate would be smaller than a standard 18 inch by 24 inch printed circuit board. Thus a number of identical systems can be fabricated from a single printed circuit board. To do this a photolithographic process is stepped and repeated across the printed circuit board to create a plurality of identical patterns.

As an alternative, it may be desirable for more than one system to be created on a printed circuit board where two or more unique systems and patterns are created and manufactured at the same time.

To form a substrate in accordance with another embodiment of this invention, plastic such as Mylar, Melinex or Delrin may be injected into a mold to produce the desired cavities with the specific angled side-walls, which may vary from vertical to 45 degrees or greater. All cavities will have their largest dimension on the same side of the substrate. The cavities in this embodiment will be through-hole cavities and the thickness of the substrate can vary from a few thousandths of an inch to more than one quarter of an inch. Typically, the cavities will be similar in thickness to the component packages that will be inserted into them. However, if the cavity is made using angled side-walls, components with similarly angled sides will naturally center themselves when inserted.

A planarizing layer, such as a planar stainless steel plate, of the same lateral dimensions as the aforementioned substrate, is temporarily attached to the side of the substrate where the cavity dimensions are smaller. Various methods can be used to attach the planarizing layer to the substrate including clamps or temporary adhesives.

Packaged component parts that have conductive lands on the package's topside in either an array or peripheral pattern are manufactured with angled side-walls that typically match the angles of the cavity into which they will be inserted. Typically these packages are laminate type packages of the same material used to make well-known Ball-Grid-Arrays (BGA). The angles on the packaged components can be made using a scoring tool whose blade has a specific angle. The laminate packages are singulated by scoring through the laminate from the topside, creating an angled package side that makes the topside of the package smaller than the bottom surface.

In one method of fabricating the structure of this embodiment of this invention, the singulated, trapezoidal-shaped packaged components are inserted into their matching cavities on the substrate such that the topside of each packaged component is face-down in its cavity. A prepreg layer is applied to the backside of the integrated structure and the temperature and pressure is increased causing the prepreg to soften and flow around the packaged components and into all crevices that may exist between component packages and the substrate. The temperature is lowered, pressure is released and the cured prepreg permanently holds the packaged components in their respective cavities forced into coplanarity with the top surface of the substrate. The planarizing layer may then be removed to leave exposed what will be the top surface of the substrate and the land-containing surfaces of the packaged components. Conductive metal, such as copper, is then deposited over the entire top surface of the integrated structure, covering the top surface of the original substrate as well as the exposed surfaces and the lands and/or the bonding pads of the packaged components. The metal may be plated or applied by other means such as sputtering or evaporation. A photosensitive material is then applied and the interconnect pattern is defined and etched using standard photolithographic processing to produce the desired electrically conductive interconnect pattern.

While this invention requires an interconnect or routing layer or layers to be formed over or under the top surface of the substrate and over the exposed conductive lands or pads on the packaged components which are mounted in cavities on the substrate, this additional routing layer can be economically and easily formed using standard integrated circuit and printed circuit board processing techniques applied to the substrate. As an additional feature of this embodiment, conductive traces can be formed in one or more layers within the substrate and even under the packaged components contained in the substrate's cavities.

The substrate fabricated in accordance with this invention may be a mother substrate which contains replicas of smaller substrates which will be singulated from the large mother substrate after the packaged components have been placed in the appropriate cavities in the mother substrate. The result will be a plurality of identical or different systems which may be formed simultaneously in a single large substrate which is then singulated into the smaller, individual substrates.

Among the advantages of this invention is that lead no longer is present either as part of solder paste, solder balls or as part of electrical contacts on the packaged components. Thus, this invention eliminates lead from the component packages and from the substrate and thus is environmentally friendly, lowers package costs by eliminating the need for solder balls and for nickel-gold plating and eliminates the thermal cycle assembly required to solder each package to the substrate contacts.

The planar surface of the substrate with the one or more packaged components mounted in one or more cavities formed as part of the substrate, or pressed into the heated substrate, results in a thinner profile for the substrate and makes possible the use of standard photolithographic techniques to form the electrically conductive interconnections between the lands or pads on the packaged components and any lands or pads on the substrate. Thus, the assembly operation will be lower cost than the prior art assembly operation. Moreover, all electrically conductive interconnects formed on the substrate to interconnect the packaged components will be available for visual inspection thereby improving the quality of the substrate assembly.

The resulting structure incorporating one or more packaged components provides a thinner cross section than available in the prior art, is capable of being manufactured at lower total cost than in the prior art at least because of the elimination of the need for solder paste and solder balls from the component packages contained thereon, is environmentally friendly and is structurally robust because of the monolithic nature of the composite structure. The structure of the invention also provides improved thermal and AC performance of the electronic system formed therein, the latter resulting from shorter electrical contacts with less inductance, less capacitance and in most cases, lower resistance than in the prior art.

This invention will be more fully understood in view of the following detailed description taken together with the drawings.

### DESCRIPTION OF THE DRAWINGS

FIG. 1 shows in cross section a prior art substrate 13 containing mounted thereon a packaged component such as an integrated circuit chip 11-1 using solder balls 12-1 through 12-N;

FIG. 2 shows a cross section of a substrate 23 containing a cavity 25 formed therein with a packaged integrated circuit 21 (shown as a DRAM) placed in the cavity and a conductive routing layer 24 placed on top of both the packaged DRAM 21 and the substrate 23;

FIG. 3a shows a top plan view of substrate 33 containing a plurality of cavities 35 each capable of containing a packaged component such as an integrated circuit device;

FIG. 3b illustrates a side-view of the structure shown in FIG. 3a;

FIG. 3c illustrates cross sectional views of packaged components suitable for placement in the cavities 35 formed in the substrate 33 of FIG. 3a;

FIG. 4a shows a plan or top view of a substrate in accordance with this invention wherein the cavities 45 formed in the substrate for receipt of packaged components have tapered side walls 47;

FIG. 4b shows a cross section of a portion of FIG. 4a illustrating the tapered sidewalls associated with cavities 45 provided for receiving the packaged components;

FIG. 4c shows packaged components with tapered sidewalls for insertion into the corresponding cavities 45 shown in FIGS. 4a and 4b;

FIGS. 5a-5c illustrate various steps in the manufacture of a monolithic substrate containing at least one packaged component in accordance with this invention;

FIGS. 6a-6d illustrate an alternative method of fabricating a monolithic substrate containing one or more packaged components in accordance with this invention;

FIGS. 7a-7c illustrate a third method of fabricating a monolithic substrate containing at least one packaged component in accordance with this invention;

FIGS. 8a and 8b each show an isometric view of a monolithic substrate containing three packaged components in accordance with the principles of this invention; and

FIG. 9 shows an embodiment of this invention suitable for implementation using pick and place equipment.

### DETAILED DESCRIPTION

The following detailed description is meant to be illustrative only and not limiting. Other embodiments of this invention will be apparent to those of ordinary skill in the art in view of this disclosure.

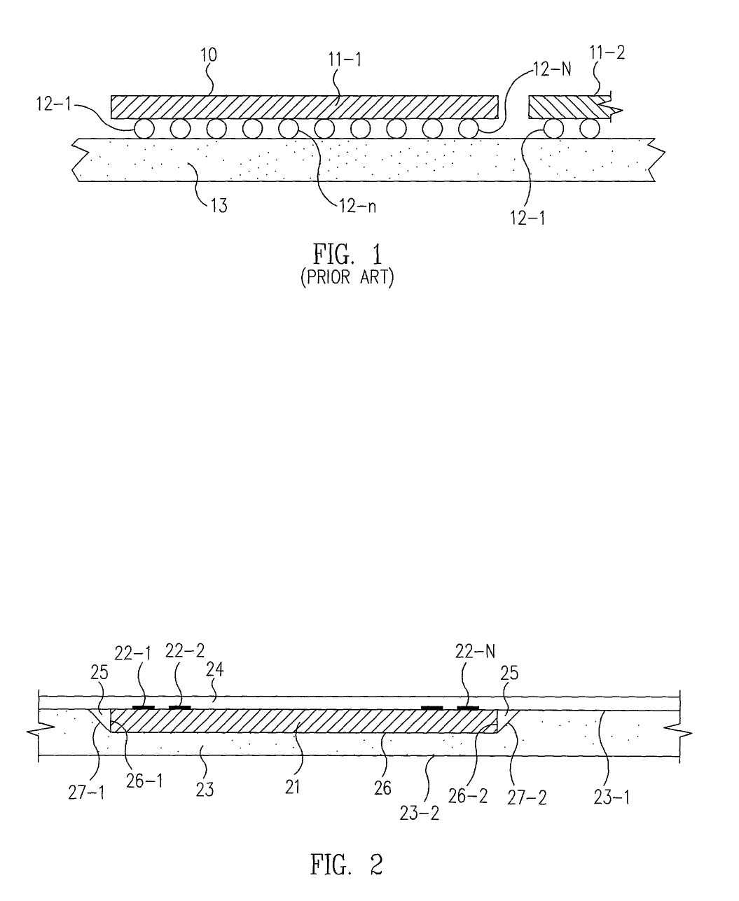

FIG. 2 shows a cross sectional view of a substrate such as a printed circuit board 23 containing therein a packaged integrated circuit 21 (for example a DRAM, but which can be any other type of memory, analog circuit or integrated circuit such as a micro-controller, micro-processor or logic circuit) placed in cavity 25. Cavity 25 is shown in cross sectional view as having tapered sides 27-1 and 27-2. Cavity 25 has four sides all of which would be tapered as shown by the two tapered sides 27-1 and 27-2. Alternatively, cavity 25 can have only two or three sides tapered as shown by the two tapered sides 27-1 and 27-2 with the remaining sides or side being essentially vertical or a substantially different angle relative to the top surface of the package and the substrate. The advantage of having one side vertical is that the packaged component then can be placed in the cavity in only one way thereby preventing erroneous placement of a packaged component in the cavity. Alternatively, the package can have a side with a proturberance or concavity which matches a corresponding concavity or protuberance in the side of the cavity in the substrate thereby to prevent a packaged component from being erroneously placed in the cavity.

Packaged integrated circuit 21 is held in the cavity using an epoxy glue or other suitable adhesive material spread along interface 26 between packaged component 21 and the printed circuit board 23 to hold packaged component 21 in cavity 25. The packaged component 21 is shown to have straight, vertically-oriented, non-tapered sides of which sides 26-1 and 26-2 are shown. The void between slanted side 27-1 and vertical side 26-1, for example, or between vertical side 26-2 and tapered side 27-2, for example, is filled with a deposited epoxy or other appropriate filler material. Typically this filler material is not electrically conductive.

Conductive layer 24 (also sometimes called a routing layer) is then deposited on the top surface of the packaged component 21 as well as on the top surface 23-1 of substrate 23. Routing layer 24 covers electrically conductive lands 22-1 through 22-N (sometimes called “conductive pads” or “pads”) formed on the exposed surface of packaged component 21 to allow electrical connection to be made to the component contained within packaged component 21. The electrical connection to land 22-1, for example, is made by the deposited layer 24 forming an electrically conductive adherent connection to conductive land 22-1 following the formation of layer 24 (which typically can be formed by low temperature chemical vapor deposition, low temperature evaporation, sputtering, electroless plating or electroplating). Conductive layer 24 is masked with an appropriate masking material such as a photoresist which is patterned in a well known manner, and then etched (either a wet etch or a dry etch) to remove unwanted portions of layer 24. The resulting structure forms an electrically conductive interconnect to electrically connect each of lands or conductive pads 22-1 through 22-N to other appropriate portions of the electrical circuitry which make-up part of printed circuit board 23 or to input/output pins from printed circuit board 23. Such input/output pins are designed to be inserted into sockets making up part of the system of which board 23 will be a part, thereby to allow one or more components formed on printed circuit board 23 to be electrically connected to the other printed circuit boards in the system.

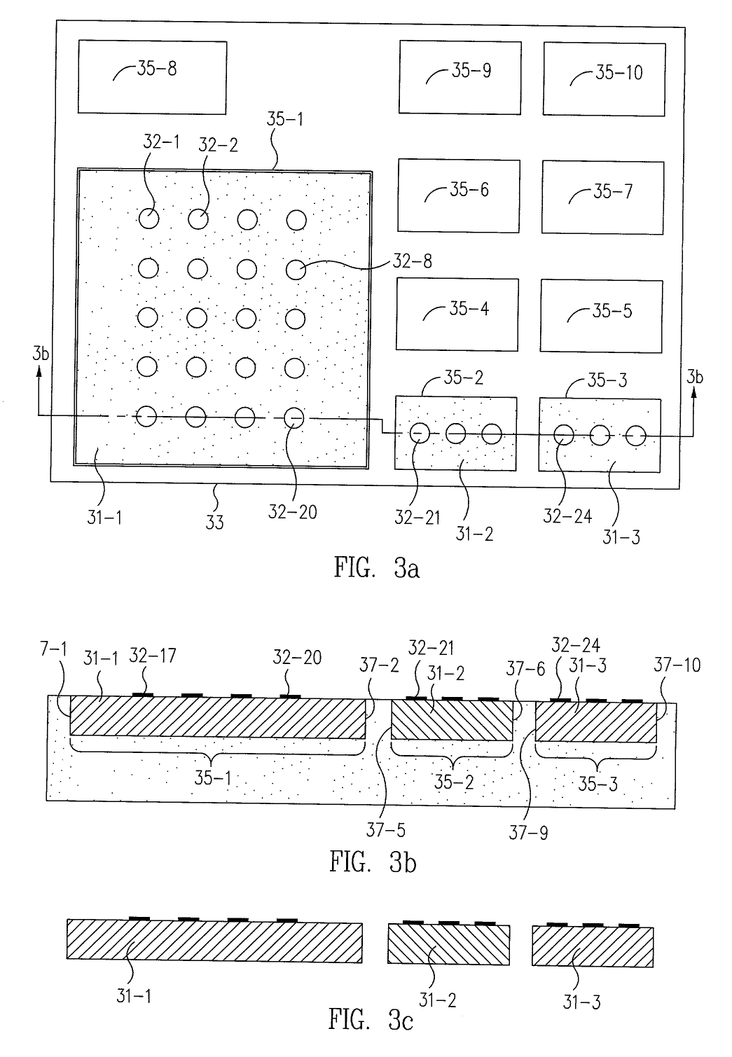

FIGS. 3a and 3b show additional structure in accordance with this invention. Printed circuit board 33 contains a plurality of cavities 35-1 through 35-10 each with vertical sidewalls suitable for receiving a packaged component such as a packaged integrated circuit. Shown in plan view in FIG. 3a is package 31-1 containing therein an integrated circuit or other electrical component which requires output lands or pads 32-1 through 32-20 to be formed on the exposed surface of the package. Shown in cross sectional view in FIG. 3b, packaged component 31-1 is placed within cavity 35-1 such that what would normally be the top surface of the packaged component 31-1, if the packaged component 31-1 had been mounted conventionally on a regular printed circuit board, is placed on the bottom of the cavity 35-1 and the conductive lands 32-1 through 32-20 face outward and are readily visible on the top surface of the printed circuit board 23. Likewise, packaged components 31-2 and 31-3 are similarly placed in cavities 35-2 and 35-3 respectively. Epoxy glue (not shown) is used to firmly hold each component 31-1, 31-2 and 31-3 in its respective cavity 35-1, 35-2 and 35-3. Alternatively, any other appropriate adhesive used in the PCB industry may be used.

The vertical side walls 37-1 through 37-10 of the cavities 35-1 through 35-3, respectively, are sized so as to allow packaged components 31-1 through 31-3 to fit snuggly within the cavities 35-1 through 35-3, respectively. To ensure that the packaged components 31-1 through 31-3 remain in these cavities 35-1 through 35-3, respectively, an adhesive such as epoxy glue is applied not only to the bottom of the cavity but also the side walls of the cavity. The adhesive allows each cavity 35-1 through 35-10 to be slightly larger than the packaged component which would be placed in the cavity yet at the same time firmly hold the packaged component within the cavity.

FIG. 3c shows a cross sectional view of the packaged components 31-1 through 31-3 which are placed in cavities 35-1 through 35-3 as shown in FIGS. 3a and 3b. The packaged components 31 can be integrated circuits including memory, logic or analog, or any other packaged components suitable for placement on a printed circuit board to form an operational circuit.

In FIG. 3a, cavities 35-4 through 35-10 are shown formed in the printed circuit board 33. However, for simplicity, no packaged components are shown in these cavities although in practice each cavity within a printed circuit board will receive a packaged component.

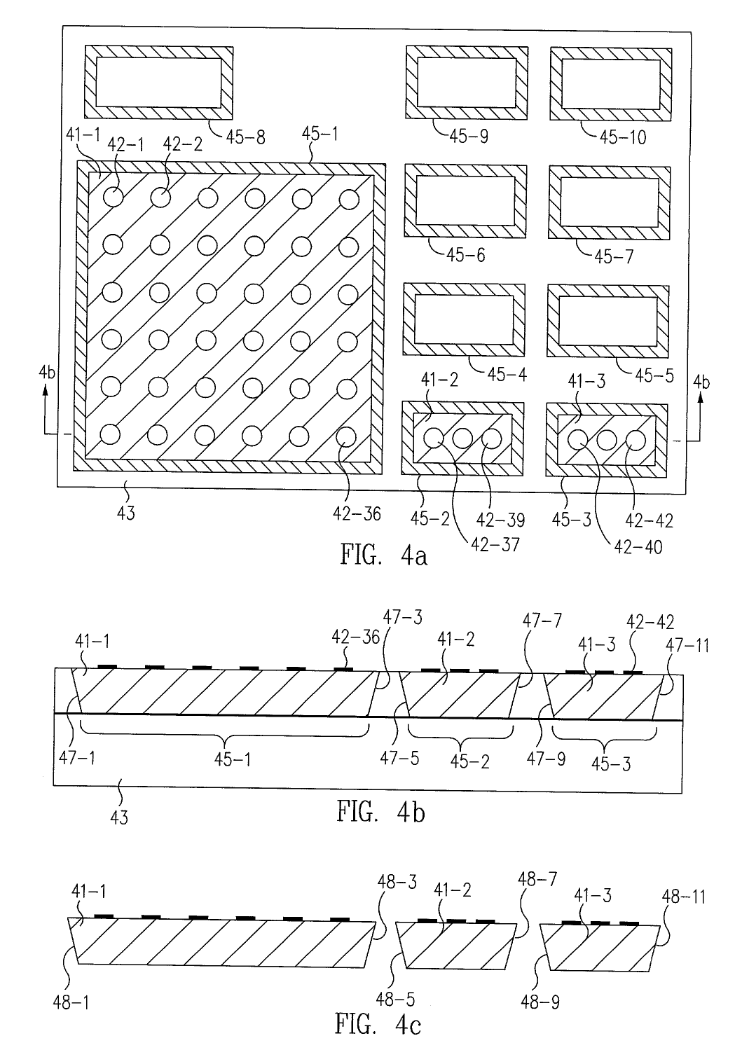

FIGS. 4a and 4b show an alternative embodiment of this invention wherein cavities 45-1 through 45-10 are formed in much the same manner as the cavities 35-1 through 35-10 in FIG. 3a except the sides 47 (such as sides 47-1 through 47-4 associated with cavity 45-1 (only sides 47-1 and 47-3 are shown), sides 47-5 through 47-8 associated with cavity 45-2 (only sides 47-5 and 47-7 are shown), sides 47-9 through 47-12 associated with cavity 45-3 (only sides 47-9 and 47-11 are shown) and the corresponding sides associated with each of cavities 45-4 through 45-10) are tapered such that the top of each cavity 45 in the printed circuit board 43 occupies a wider area than the bottom of each cavity 45 sunk part way into the printed circuit board 43. The packaged components 41-1 through 41-3 likewise have tapered sides 48-1 through 48-12 which may or may not have a taper which matches the taper of the sides of the cavity. While preferably the tapers on the sides 48 of each packaged component 41 match the tapers on the sides 47 of the cavity 45 in which the packaged component is placed, this invention allows the tapers on the sides 48 of the packaged components 41 to differ from the tapers on the sides 47 of the receiving cavities 45 and still allow the packaged components 41 to be properly assembled in the underlying substrate or printed circuit board 43. However, if the tapers on the sides 48 of the packaged components 41 match the tapers on the sides of the cavities 45 in which the packaged components 41 are to be inserted, then the packaged components 41 can be easily inserted into the corresponding cavities 45 and the tapered sides of each of the cavities 45-1 through 45-10 assist in properly aligning the packaged components 41 in their corresponding cavities 45. Conductive lands (of which lands 42-1 through 42-36 are shown associated with packaged component 41-1, lands 42-37 through 42-39 are shown associated with packaged component 41-2 and lands 42-40 through 42-42 are shown associated with packaged component 41-3) are formed on the exposed surfaces of the respective packages to allow a conductive layer to be deposited over the top surface of the structure including the exposed surfaces and lands of each packaged component 41 and the top surface of the printed circuit board 43, patterned into conductive leads and then etched away to form conductive leads connecting selected ones of lands 42 to other lands and/or to conductive traces or lands or pads (not shown) on the printed circuit board 43.

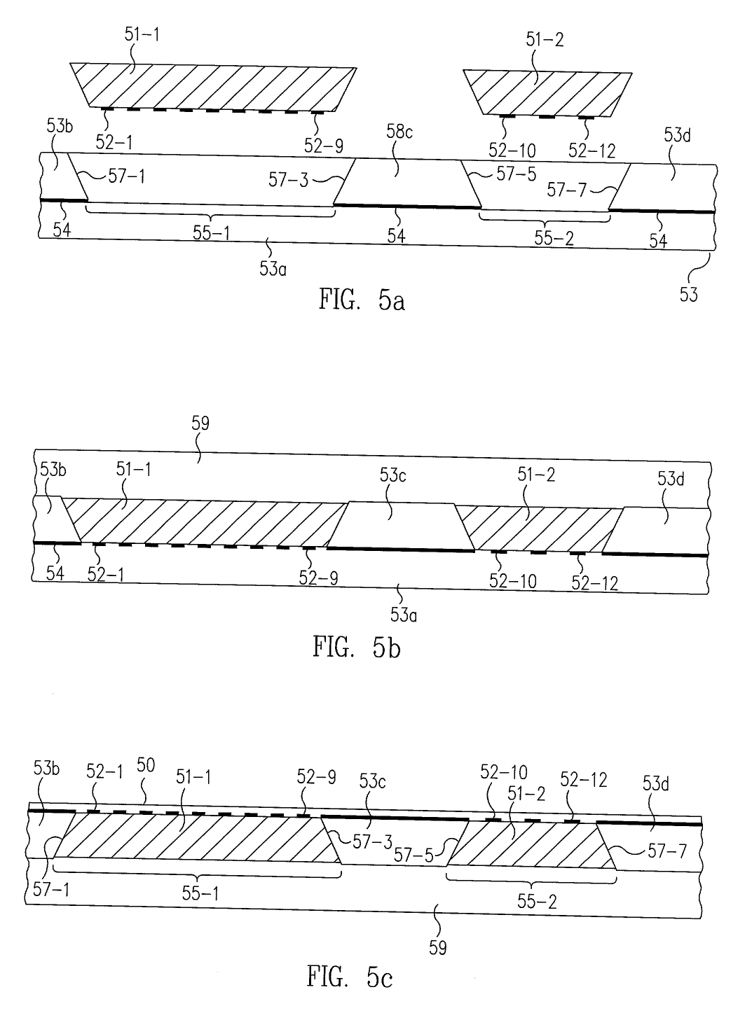

FIGS. 5a through 5c show an alternative embodiment for fabricating a substrate containing one or more packaged components 51 in accordance with this invention. A plastic substrate 53 (of which sections 53b, 53c and 53d are shown) is placed on a planarizing layer 53a which typically is sacrificial and is not part of the plastic substrate 53. The term plastic is used here and in the specification to include all types of plastic based materials including laminates formed using epoxy, BT and cyanate resins strengthened with woven glass or aramid cloth, for example. Such materials are commonly used in the PCB industry and any laminate material of the type used in the PCB industry is appropriate for use in this invention. A metal layer 54 is formed on the bottom of substrate 53 between substrate 53 and planarizing layer 53a. As part of the fabrication process, cavities 55-1 and 55-2 must be formed in material 53 which makes up the substrate. This is done by any one of several processes, such as routing with a suitably tapered bit or molding, which results in tapered sidewalls 57-1 through 57-4 for cavity 55-1 and tapered sidewalls 57-5 through 57-8 for cavity 55-2. The resulting structure is shown in cross-section in FIG. 5a. The packaged components 51-1 and 51-2 can then be placed in the cavities 55-1 and 55-2, respectively, followed by the formation of a prepreg laminate layer 59 over the back sides of these inserted packages 51-1 and 51-2. Following this step, the structure looks somewhat as shown in FIG. 5b except the planarizing layer 53a still remains on the structure. Planarizing layer 53a can, for example, be stainless steel, quartz, or any other planar material which is capable of being removed from the structure prior to completion of the structure but after insertion of the packaged components 51 into the cavities 55 associated with the plastic substrate 53. Material 53, which makes up the plastic substrate, will be formed using a mold made of stainless steel, aluminum or other appropriate material, to create the substrate with cavities of which cavities 55-1 and 55-2 are shown with tapered side walls 57-1 through 57-8 (of which sidewalls 57-1, 57-3, 57-5 and 57-7 are shown). Now, planarizing layer 53a is physically removed (planarizing layer 53a in one embodiment merely supports and is not permanently attached to plastic substrate material 53 and thus can be easily removed). As a result of removing planarizing layer 53a, the lands 52 on the bottom surfaces of package components 51-1 and 51-2 are exposed. Copper layer 54 is also exposed at this time. Conductive lands 52 (of which lands 52-1 through 52-9 are shown in FIG. 5a) have been formed on the bottom surface of packaged component 51-1 and conductive lands 52 (of which lands 52-10 through 52-12 are shown in FIG. 5a) have been formed on the bottom surface of packaged component 51-2.

FIG. 5b shows packaged components 51-1 and 51-2 placed in cavities 55-1 and 55-2 respectively. Conductive lands 52 are at the bottom of the cavity and not yet accessible to conductive leads which are to be formed on the plastic substrate. A laminate layer 59, such as a well-known prepreg layer, is then formed over the top surface of substrate 53 to firmly hold packaged component 51-1 and packaged component 51-2 in cavities 55-1 and 55-2, respectively. Prepreg laminate layer 59 is applied under heat and pressure to attach to the portions 53b through 53d of plastic substrate 53 and to fill all crevices between the inserted component packages 51-1 and 51-2 and the walls 57 of the cavities 55-1 and 55-2 in which packaged components 51-1 and 51-2, respectively, are placed. Metal layer 54 typically is copper although any other appropriate electrically conductive metal can also be used. The metal 54 can be placed on the bottom of the substrate 53 after the formation of the cavities 55 in the substrate material 53, or metal 54 can even be placed upon the bottom surface of the substrate 53 after placement of the components 51 in the corresponding cavities 55. This latter alternative may require masking the exposed surfaces of each of the packaged components 51 to protect the conductive lands 52 exposed on the package surfaces from being contacted by metal layer 54 during the formation of metal layer 54. Alternatively, however, these lands 52 can be allowed to be contacted by the metal layer 54 and then a photolithographic process can be used to form the interconnects directly between lands 52 on one packaged component 51 and adjacent lands 52 on other packaged components 51 or electrically conductive traces on the substrate 53 as part of the final processing step to form the electrical interconnect structure associated with the printed circuit board 53.

The substrate, now made up of those materials of which cross sections 53b, 53c, and 53d are shown and the laminate layer 59, is flipped over (as shown in FIG. 5c) such that lands 52-1 through 52-12 are exposed. An electrically conductive layer of material 50 (typically copper) is then formed over the top surfaces of both metal layer 54 and lands 52, patterned and etched to form electrically conductive leads uniquely linking each of lands 52 to a corresponding conductive land on another packaged component or to a conductive trace (not shown) on the substrate 53. The laminate layer 59 now forms part of the substrate 53 and packaged components 51-1 and 51-2 are firmly mounted in the plastic substrate 53 and held in place by the prepreg laminate layer 59 which adheres to and forms around parts of the packaged components 51. The sloping sides 57 of cavities 55-1 and 55-2 (of which sides 57-1 and 57-3 are shown for cavity 55-1 and sides 57-5 and 57-7 are shown for cavity 55-2) also assist in holding packaged components 51 in place.

The packaged components shown in FIGS. 4a through 4c and 5a through 5c have tapered sides. The use of tapered sides is not necessarily required and the invention likewise can use packaged components with vertical flat sides such that the packaged components will rest in a tapered cavity and be automatically aligned by the tapered sides of the cavity to properly fit within the cavity. The use of laminate layer 59 to then hold the packaged components with vertical sides in the appropriate tapered cavity ensures that the packaged components are properly aligned in each of their respective cavities. Of course, packaged components with vertical sidewalls can be placed in cavities with vertical sidewalls.

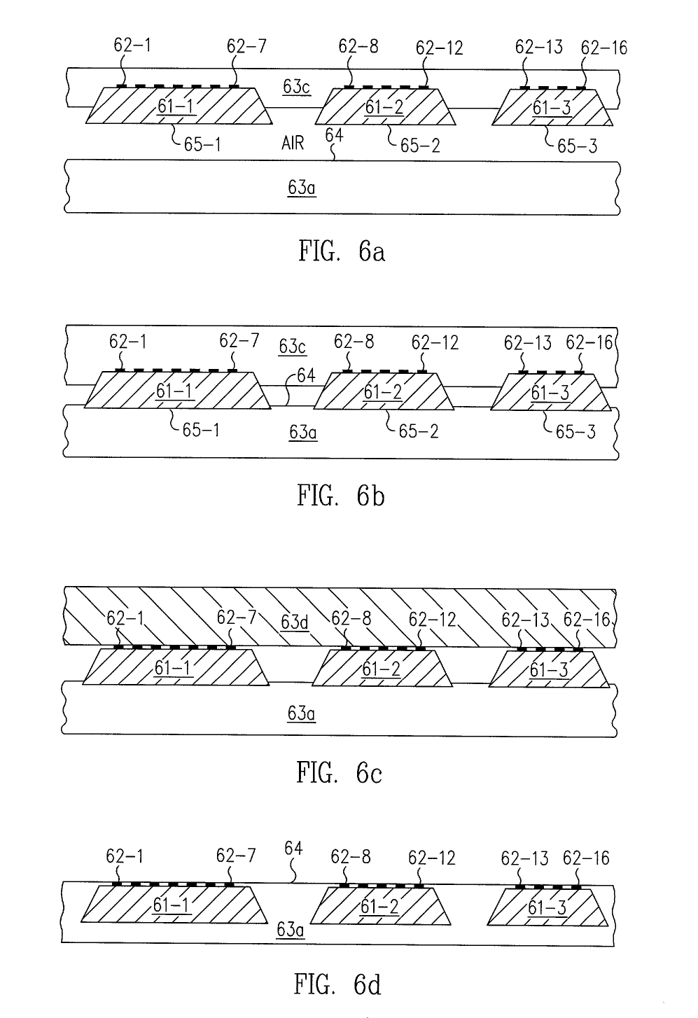

FIGS. 6a through 6d illustrate another method (using heat-softened material), of fabricating the monolithic substrate of this invention containing one or more packaged components.

In FIG. 6a, a substrate 63a of thermo-plastic material, epoxy or other thermo-setting plastic is shown below packaged components 61-1, 61-2 and 61-3 held spaced above substrate 63a by a template 63c. Template 63c holds packaged components 61-1, 61-2 and 61-3 in place by vacuum, adhesive, or gravity if the structure comprising substrate 63a and template 63c is flipped 180° such that substrate 63a is on top and template 63c is on the bottom.

The packaged components 61-1, 61-2 and 61-3 may be held in place on substrate 63a by adhesive or by pressing packaged components 61-1, 61-2 and 61-3 slightly into the top surface 64 of substrate 63a at an elevated temperature sufficient to soften, make tacky and allow to flow the material of substrate 63a.

The backsides 65-1 through 65-3 of the packaged components 61-1 through 61-3, respectively, that are held in position by the template 63c are brought into contact with plastic substrate 63a. Thermoplastic materials such as Mylar, Melinex, Kaladex or Delrin may be used for this substrate 63a because they can be heated and cooled quickly, enabling rapid processing time. Thermoset materials or combinations of thermoset and thermoplastic materials may also be desirable. Template 63c can remain in position during curing, or the template 63c can position the packaged components 61-1 through 61-3 onto another structure that securely holds the components by a vacuum or adhesive in fixed positions during the subsequent processing after removal of template 63c.

In FIG. 6c, a planar structure 63d (such as a stainless steel, aluminum or quartz plate) is placed on top of packaged components 61-1, 61-2 and 61-3, the entire structure is heated, and pressure is applied through the planar structure 63d to packaged components 61-1, 61-2 and 61-3. While planar structure 63d is shown in FIG. 6c to be solid, an alternative embodiment provides openings through planar structure 63d to allow a vacuum to be pulled through planar structure 63d to hold packages 61-1, 61-2, and 61-3 in place relative to planar structure 63d and substrate 63a during the subsequent process steps to which the structure is subjected. Alternatively, an adhesive can be placed on the lower surface of planar structure 63d contacting packaged components 61-1, 61-2 and 61-3 to hold the packages 61-1, 61-2 and 61-3 in place during the subsequent process steps. A cleaning step can then be employed to remove any residual adhesive from the top surface of substrate 63a and the exposed surfaces and lands of packages 61-1, 61-2 and 61-3 upon completion of the processing steps involving planar structure 63d.

The surface of planar structure 63d in contact with the packaged components may be coated with a soft teflon film to protect the land-carrying front side of the packaged components 61-1 through 61-3 and to ensure ease of separation of the planar structure 63d from the underlying composite structure of packaged components 61 and substrate 63a. If adhesive is used to hold components in position during subsequent processing, this teflon film can be selectively applied, by stencil printing or other processes, so as not to coat the areas where an adhesive will be applied to hold in place the packaged components 61. The entire structure rests on a flat surface (not shown) during this operation. A heated press, such as those used in printed circuit board manufacturing, is pressed against the plastic substrate 63a, and pressure is applied between the press and the planarizing layer 63d. A vacuum may be drawn on the substrate during the subsequent processing to remove trapped gasses and air, and prevent voids from occurring within the substrate. Those skilled in the arts will be familiar with vacuum presses in the printed circuit board industry that are used for this purpose. The press is heated to allow the plastic to flow, and the substrate plastic forms around the packaged components 61-1 through 61-3 and is stopped by the planarizing layer 63d to create a composite structure with the substrate top surface 64 substantially coplanar with the top surfaces of the embedded plastic components 61-1 through 61-3. The temperatures and pressure used for this process will vary depending upon the choice of plastics. The press and the integrated substrate are returned to room temperature, permanently securing the packaged components 61-1 through 61-3 as part of the planar structure. As an alternative, heat and pressure can also be applied to the planarizing layer 63d instead of or in addition to the heat and pressure applied to the back of the plastic substrate 63a. The packaged components 61-1, 61-2 and 61-3 are then pressed into substrate 63a until the top surfaces of packaged components 61-1, 61-2 and 61-3 (which contain conductive lands 62 of which lands 62-1 through 62-7 on packaged component 61-1, lands 62-8 through 62-12 on packaged component 61-2 and lands 62-13 through 62-16 on packaged component 61-3 are shown) are essentially coplanar with the top surface 64 of substrate 63a. The final position of packaged components 61-1, 61-2 and 61-3 is shown in FIG. 6d where the top surfaces of packaged components 61-1, 61-2 and 61-3 are approximately coplanar with the top surface 64 of substrate 63a. Lands 62-1 through 62-16 are shown to have their top surfaces in a plane, which preferably is substantially coextensive with the top surface 64 of substrate 63a. Typically, a dielectric is formed between the lands on the top surfaces of packaged components 61-1 through 61-3 to protect any underlying circuitry (including electrically conductive traces) formed beneath the dielectric. The top surfaces of the lands 62 and the dielectric are substantially coplanar. Because substrate 63a is made of a thermo-plastic material, epoxy or thermo-setting plastic, which will soften and flow at a temperature beneath the temperature at which the material of packages 61 softens, the final structure includes packaged components 61-1, 61-2 and 61-3 firmly embedded and held in the plastic material of substrate 63a. Substrate 63a is now ready for metalization to form interconnect routing or additional laminated or built up structure on the top surface 64 of substrate 63a.

In this embodiment, the template 63c is the same lateral size as the plastic substrate 63a that will be used in the fabrication of the integrated structures. The template 63c may vary in thickness from a few thousandths of an inch to a quarter of an inch or more. Each template 63c is a unique design and contains openings that are designed to hold and correctly align matching-sized packaged components 61. Template 63c in one embodiment has openings with angled sidewalls which match the angled sidewalls of the packaged components 61 that will be held by the template. This insures correct XY alignment. Since the typical system to be formed using the structures and methods of this invention is much smaller in lateral dimensions than the full sized substrate 63a, a stepped and repeated pattern can be used to create a plurality of systems on each substrate 63a.

In an alternative embodiment, packaged components 61 are placed into their respective openings in the template 63c and are held in place by a vacuum drawn through holes (not shown) appropriately placed in template 63c above the packaged components 61, a temporary adhesive, or by gravity if the openings on the template 63c are positioned in the topside of template 63c. Well known pick and place equipment can be used to place the packaged components 61 in their respective openings in template 63c. The required sidewall angles of the packaged components 61 may be created by choosing a scoring blade, for singulating the component packages with the angles on the sides of the cutting blade matching the angles of the sides of the openings in the template 63c. Thus, the component packages 61 will have sidewall angles that match the angles of the sidewalls of their respective template openings.

As an alternative embodiment, not shown in the drawing, plastic substrate 63a may have cavities located on its top surface that are aligned to components 61-1, 61-2, and 61-3, that are held in the template. The dimensions of these cavities are the same or slightly larger sized than the dimensions of the component bottoms 65-1, 65-2 and 65-3, such that the components fit into the cavities. The depth of the cavities may equal the thickness of components 65-1, 65-2 and 65-3, or they may be of a lesser or greater depth.

An alternative embodiment for accurately placing packaged components 61-1, 61-2 and 61-3 onto a substrate uses commercially available pick-and-place equipment, commonly used in surface mount assembly of packaged components (as described the prior art). Components 61-1, 61-2 and 61-3 are automatically placed onto plastic substrate 63a in specific locations according to a unique program that is created for each design. The surface of the plastic substrate 63a may have an adhesive applied, or it may be raised in temperature to make the surface tacky so as to hold in place the packaged components, 61-1, 61-2 and 61-3.

An electrically conductive material, for example, a metal such as copper, is deposited over the entire, coplanar top surface 64 (FIG. 6d) of the integrated structure, coating the exposed surface of the original substrate 63a as well as the topsides and the lands and/or bonding pads of the packaged components 61-1, 61-2 and 61-3. The metal may be plated or applied by other means such as sputtering or evaporation. A photosensitive material is then applied, the interconnect pattern is defined in a well-known manner and the conductive layer is etched to produce the desired electrically conductive interconnect pattern.

As an alternative embodiment for creating the structure shown in FIG. 6d, packaged components 61 can be accurately placed on substrate 63a using a template which is described and shown in FIG. 6a. The packaged components are then held in place on substrate 63a by a planarizing layer 63d (FIG. 6c). A vacuum can be applied to packaged components 61-1 through 61-3 through holes (not shown) in planarizing layer 63d above the packaged components to hold the packaged components 61-1 through 61-3 in place. Alternatively, an adhesive can be applied to the bottom surface of planarizing layer 63d to hold packaged components 61-1 through 61-3 in place. The resulting structure is placed in an injection mold and heated plastic is injected into the injection mold (typically a custom mold sized to receive the substrate 63a with the planarizing layer 63d attached thereto) completely covering the backside and interstitial spaces of the structure with the injected plastic. In a further modification of this process, packaged components 61-1 through 61-3 are placed on substrate 63a by template 63c, template 63c is then removed and planarizing plate 63d is placed over and in contact with the exposed land-containing surfaces of packaged components 61-1 through 61-3. Components 61-1 through 61-3 are held in place relative to planarizing plate 63d by adhesive on the adjacent contacting surface of planarizing plate 63d or by vacuum drawn though openings (not shown) in planarizing plate 63d directly above the packaged components 61-1 through 61-3. Such a vacuum holds packaged components 61-1 through 61-3 in place relative to planarizing plate 63d. Planarizing plate 63d, with packaged components 61-1 through 61-3 attached, is then placed in an injection mold and heated plastic is injected into the mold to encapsulate the packaged components 61-1 through 61-3. The resulting structure is allowed to cool and planarizing plate or layer 63d is removed from the structure to expose the lands 62-1 through 62-16 on the outward facing surfaces of packaged components 61-1 through 61-3.

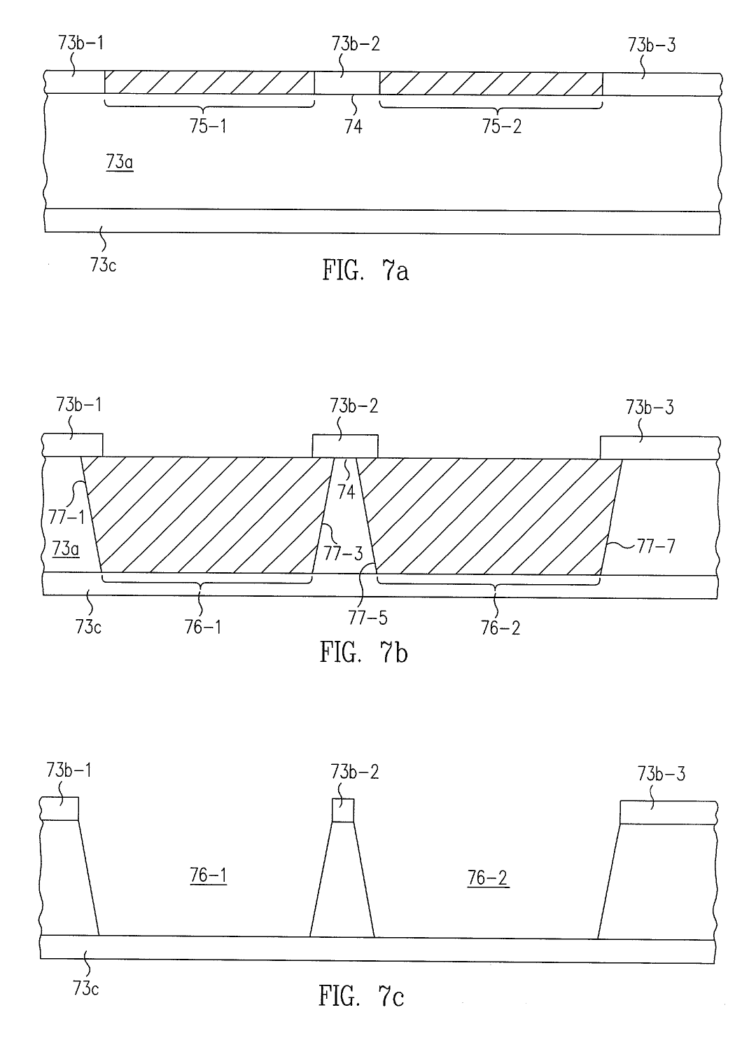

FIGS. 7a, 7b and 7c illustrate another alternative embodiment of this invention. A substrate 73a of metal has formed on its top surface 74 a layer of copper 73b. Copper 73b is then masked and etched to form openings 75-1 and 75-2 in copper layer 73b, thereby to create cavities in copper layer 73b between the cross sectional copper portions 73b-1, 73b-2 and 73b-3. A second copper layer 73c is formed on the bottom of metal layer 73a. Typically, metal layer 73a is aluminum.

In FIG. 7b, metal layer 73a is further etched through the openings 75-1 and 75-2 formed in copper layer 73b to form cavities 76-1 and 76-2 in the metal layer 73a. The copper layer 73b, of which cross sections 73b-1, 73b-2 and 73b-3 are shown, serves as an etch resistant mask. The etching through metal layer 73a automatically stops at the second copper layer 73c thereby to produce a controllable cavity depth equal to the thickness of metal layer 73a. Cavities 76-1 and 76-2 have slightly tapered sides 77-1 through 77-8 of which sides 77-1 and 77-3 are shown with respect to cavity 76-1 and sides 77-5 and 77-7 are shown with respect to cavity 76-2. Because of the lateral etching of the metal 73a, tapered sides 77-1 through 77-8 are formed during the etching process. Thus copper mask sections 73b-1 through 73b-3 are slightly undercut. Copper layer 73b can then be etched back to conform to metal 73a such that the etched cavities 76-1 and 76-2 each have an opening at the top corresponding to the maximum width of the cavities 76-1 and 76-2 in the metal layer 73a.

Finally, portions of copper layer 73c, which served as an etch stop mask, may be removed to produce through-hole cavities 76-1 and 76-2 or alternatively remain (as shown) as part of the final structure. The particular structure with copper layer 73c remaining, now shown in FIG. 7c, can be used in conjunction with electronic components to serve as a heat dissipation plane or to serve as an equal-potential plane such as a VCC plane or a ground plane.

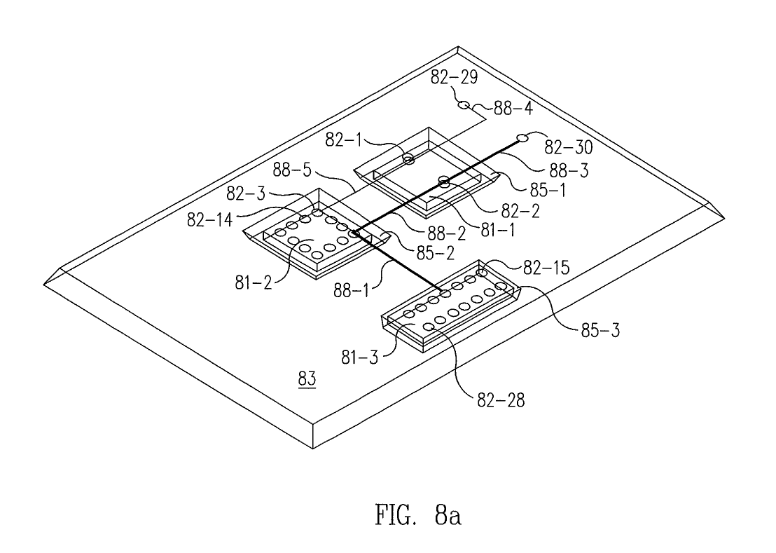

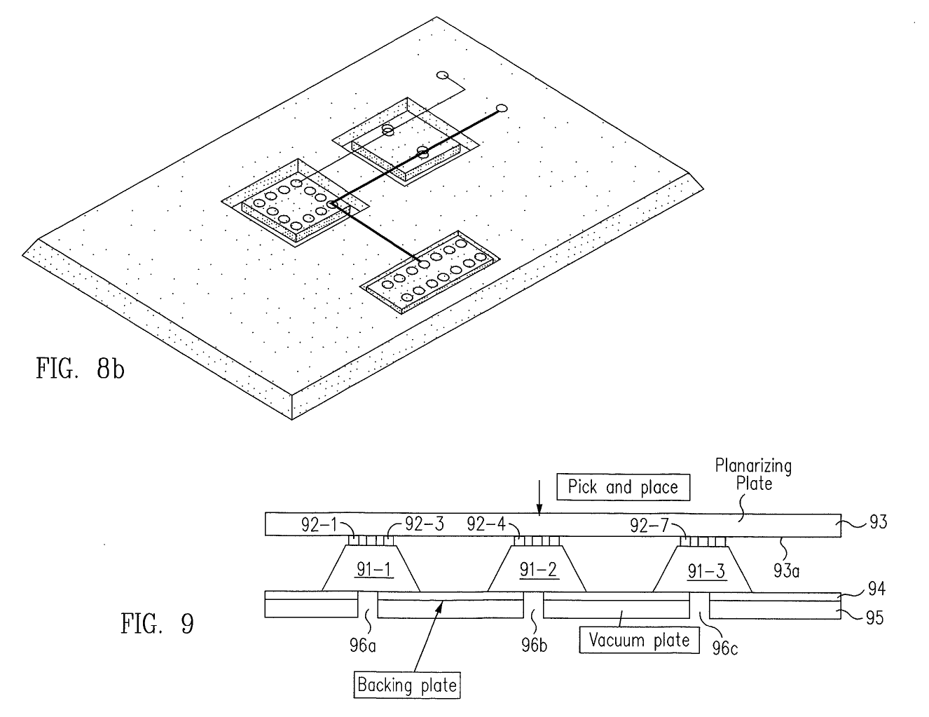

FIG. 8a shows an isometric view of a printed circuit board 83 having three cavities 85-1, 85-2 and 85-3 in which are placed three packaged components 81-1, 81-2 and 81-3, respectively. Lands 82-1 and 82-2 are shown on packaged component 81-1, lands 82-3 through 82-14 (counting clockwise) are shown on packaged component 81-2 and an additional fourteen lands 82-15 through 82-28 are shown on packaged component 81-3. Electrically conductive interconnects 88-1, 88-2, 88-3, 88-4 and 88-5 are shown interconnecting selected ones of the lands on the packaged components as well as conductive lands 82-29 and 82-30 on the printed circuit board 83. As is apparent from the isometric view of FIG. 8a, this printed circuit structure 83 includes the packaged components 81-1 through 81-3 as a monolithic, integrated part thereof adherently attached to the cavities 85-1 through 85-3, respectively, in the printed circuit board 83. The resulting structure is thinner than prior art structures and provides a monolithic, planar, integral structure, which is robust and of high quality.

FIG. 8b shows the structure of FIG. 8a covered with a protective coating over the top surface to protect the lands 82 on top of the packaged components 81 and the electrically conductive traces 88 interconnecting selected lands and traces on the printed circuit board 83. The protective coating typically can comprise a polymer, such as polyimide, or other plastic or epoxy.

Several printed circuit boards 83 of the type shown in FIG. 8a can be stacked one on top of the other to provide a compact three dimensional structure. The multiple layers of interconnects or traces on each board are connected either using through hole vias, blind vias or hidden vias. A through hole via is a via formed completely through the composite structure of printed circuit boards from the top to the bottom. A blind via is a via formed from one surface partially into the composite structure and a hidden via is a via formed internally within the composite structure but which does not extend to either the top or bottom surface of the composite structure. Conductive lands can then be used with the hidden vias to allow interconnections to be properly formed in the composite structure to provide a functioning electronic system incorporating packaged components contained in each of the printed circuit boards making up the composite structure. Typically an electrically conductive land will be used in conjunction with each through hole via or blind via on each printed circuit board which is desired to be electrically connected to other parts of the structure.

FIG. 9 shows another method of fabricating a monolithic integrated structure in accordance with this invention. A plurality of packaged components shown as components 91-1 through 91-3 are picked from a tray adjacent to the pick and place equipment. Each packaged component 91-1 through 91-3 is then placed in an appropriate location on an underlying backing plate 94. Typically, backing plate 94 can be a laminate material, a thin metal such as copper or aluminum, nichrome, stainless steel or any other appropriate metal, or ceramic, for example. Openings 96a, 96b and 96c formed through backing plate 94 allow a vacuum to be pulled on the packaged components 91-1 through 91-3 to be placed over these openings by the pick and place equipment. Packaged components 91-1 through 91-3 are shown with tapered sides such that the surface of each packaged component having the largest dimension is directly adjacent to and in contact with backing plate 94. Obviously the sides of the packaged components 91-1 through 91-3 do not need to be tapered and could be vertical relative to backing plate 94. Vacuum plate 95 beneath backing plate 94 supports backing plate 94. Holes 96a, 96b, and 96c are shown formed through both backing plate 94 and vacuum plate 95. Obviously, vacuum plate 95 would be part of the vacuum system including a vacuum chamber for allowing a vacuum to be pulled through the openings 96a, 96b and 96c onto packaged components 91-1, 91-2 and 91-3 respectively. Conductive lands 92-1 through 92-9 are shown on the top surfaces of packaged components 91-1, 91-2 and 91-3. Directly adjacent these conductive lands is placed planarizing plate 93. The surface 93a of planarizing plate 93 in direct contact with lands 92 typically will have placed on it a Teflon or other material which makes it easy to remove the planarizing plate from contact with both packaged components 91-1 through 91-3 and the material to be inserted between these packaged components during the manufacturing process associated with this invention. Typically, a thermoplastic material of the type use for injection molding would be injected into the interstitial spaces between packaged components 91-1 through 91-3 out to the edges of the mold in which planarizing plate 93, backing plate 94 and vacuum plate 95 are placed. Alternatively, a preformed substrate of plastic material (not shown) can be placed over packaged components 91-1 through 91-3 with openings in the preformed substrate for allowing the preformed substrate to slip down into the interstitial regions between the packaged components 91-1 through 91-3. This preformed plastic substrate would then be heated to flow and form around the packaged components 91-1 through 91-3.

Under some circumstances, backing plate 94 will be flexible in which case different thickness of packaged components 91-1 through 91-3 can be accommodated on the same substrate.

The planarizing plate 93 can also be used to push excess plastic down into the interstitial spaces between the packaged components 91-1 through 91-3 to ensure a uniform and substantially equal thickness structure formed from the plastic in the interstitial regions between these packaged components 91-1 through 91-3.

The planarizing plate 93 will ensure that the plastic formed in the interstitial regions between the packaged components 91-1 through 91-3 will have a planar surface substantially co-planar with the lands 92-1 through 92-9 on the exposed surfaces of the packaged components 91-1 through 91-3. Should there be any irregularities in thickness of the resulting structure, the backside surface will have to absorb those irregularities either by having bumps or dimples in it. Thus, in some embodiments, the backside plate 94 must be flexible so that when vacuum plate 95 is removed prior to the molding process, the planarizing layer 93 can ensure that the top surfaces of packaged components 91-1 through 91-3 are in the same plane even if this causes a lack of planarity in backside plate 94.

One of the advantages of this invention is that it allows the accurate placement of the packaged components relative to one another on this substrate and further allows the maintenance of this placement throughout the process.

Pick and place tooling allows the packaged components to be placed on the substrate or the template as the case may be and visibly checked for accurate placement. The packaged components can then be placed and glued to this substrate or otherwise held on the substrate in a manner that maintains their relative locations on the substrate throughout the process.

While this invention has been described in terms of several embodiments, other embodiments will be obvious to those skilled in the art in view of this disclosure.

What is claimed:

1. Structure comprising:
a substrate having a top surface;
at least one cavity formed in said substrate adjacent said top surface; and
at least one packaged component placed in said at least one cavity so that each of said at least one packaged component has a visible surface approximately coplanar with the top surface of said substrate.

2. Structure as in claim 1 wherein each of said at least one packaged component includes a plurality of electrically conductive lands formed on said visible surface.

3. Structure as in claim 2 including a conductive layer formed over the visible surface of each of said at least one packaged component, said plurality of electrically conductive lands and the top surface of said substrate.

4. Structure as in claim 3 including conductive traces formed on the top surface of said substrate.

5. Structure as in claim 4 wherein said conductive layer is patterned to form a plurality of conductive leads interconnecting selected ones of the lands on each of said at least one packaged component to selected ones of said conductive traces.

6. Structure as in claim 5 wherein said substrate comprises a printed circuit board and said conductive traces on said printed circuit board interconnect each of said at least one packaged component with other packaged components similarly placed on said printed circuit board.

7. Structure as in claim 1 wherein said substrate contains a plurality of cavities, each of said plurality of cavities containing a corresponding packaged component.

8. Structure as in claim 7 wherein each of said corresponding packaged components has a visible surface approximately coplanar with the top surface of said substrate.

9. Structure as in claim 8 wherein each of said packaged components has a plurality of electrically conductive lands formed on surface.

10. Structure as in claim 9 wherein said plurality of electrically conductive lands formed on the visible surface of said packaged component allows electrical connection to electrical circuitry contained in said packaged component.

11. The method of fabricating a printed circuit board having a top surface which comprises:
forming a plurality of cavities in said printed circuit board, each said cavity having an opening in said top surface;
placing a corresponding plurality of packaged components in said plurality of cavities such that a visible surface of each of said packaged components is substantially coplanar with said top surface, each said packaged component having a plurality of electrically conductive lands formed on the visible surface of said packaged component;
forming a conductive layer on the top surface of said printed circuit board, on the visible surfaces of said packaged components and on the plurality of conductive lands on each visible surface; and
patterning the conductive layer to form a conductive interconnect to interconnect the packaged components into a desired circuit.

12. The method of claim 11 wherein said step of patterning the conductive layer comprises:
forming a photoresist material on said conductive layer;
removing selected portions of said photoresist to expose portions of said conductive layer to be removed from said structure; and
removing exposed portions of the conductive layer from the structure so as to leave said conductive interconnect.

13. The structure as in claim 1 wherein each of said cavities has tapered sides.

14. Structure as in claim 1 where each of said cavities has substantially vertical sides.

15. Structure as in claim 1 wherein the substrate is formed of a material from the group consisting of plastic, ceramic, epoxy and any combination thereof.

16. Structure as in claim 3 wherein the conductive layer comprises a metal selected from the group consisting of copper, aluminum, and a composite of copper and aluminum.

17. Structure as in claim 3 wherein said conductive layer comprises copper.

18. Structure as in claim 3 wherein said conductive layer comprises a conductive metal.

19. Structure as in claim 3 wherein said conductive layer comprises a composite layer comprised of copper laminated with a prepreg.

20. Structure as in claim 1 wherein said substrate is formed of multiple layers of conductive material formed into conductive traces and dielectric material.

21. Structure as in claim 20 wherein said substrate includes at least one electrically conductive layer formed on one surface thereof.

22. Structure as in claim 21 wherein said substrate includes a conductive plane formed below at least one of said at least one cavity.

23. Structure as in claim 22 wherein the conductive plane can be used as either a ground plane or a VCC plane.

24. Structure as in claim 22 wherein said conductive plane comprises a ground plane.

25. Structure as in claim 22 wherein said conductive plane comprises a VCC plane.

26. Structure as in claim 1 wherein said packaged component placed in said at least one cavity has a first face upon which are formed electrically conductive lands and a second face with no conductive lands, and said packaged component is placed in said at least one cavity such that the conductive lands face up and are in a plane approximately co-planning with the top surface of said substrate.

27. Structure as in claim 1 wherein each of said at least one packaged component has lands on one face and no lands on a second face and is placed into said at least one cavity such that the lands face the bottom of the cavity.

28. Structure as in claim 1 wherein each of said at least one cavity has sidewalls that are substantially perpendicular to said top surface.

29. Structure as in claim 1 wherein each of said at least one cavity has sidewalls which are angled with respect to the top surface.

30. Structure as in claim 1 wherein each of said at least one packaged component has sidewalls which form an angle with said top surface, said angle being different from the angle formed by the sidewalls of each of said at least one cavity with said top surface.

31. Structure as in claim 1 wherein said conductive layer formed over the visible surface of each of said at least one packaged component and the top surface of said substrate is formed by a process selected from the processes consisting of plating, sputtering, and evaporation.

32. Structure as in claim 1 wherein each of said at least one packaged component is held in its cavity by an adhesive, prepreg or plastic such that said packaged component is permanently attached in said cavity.

33. Structure as in claim 1 wherein each of said at least one packaged component is held in its cavity by an adhesive which forms a temporary bond between said packaged component and the cavity thereby to allow the removal and/or replacement of the packaged component from its matching cavity.

34. Structure as in claim 3 wherein said conductive layer is patterned to form an electrically conductive interconnect to carry electrical signals between each of said at least one packaged component and traces on the substrate, thereby to form an electrical system.

35. A plurality of structures, each structure comprising the structure as set forth in claim 1, said plurality of structures being stacked such that each such structure but one is on top of another such structure such that said plurality of structures thereby form a multilayer composite structure.

36. Structure as in claim 1 wherein conductive vias are formed in said substrate thereby to electrically interconnect multiple layers of conductive traces in said substrate.

37. Structure as in claim 3 wherein said conductive layer is formed from a conductive epoxy or other conductive non-metallic material and is formed into an electrical interconnect pattern.

38. A structure made of thermo-plastic or thermo-set plastic or a composite thereof, comprising:
a substrate having a top surface;
at least one cavity formed in said substrate, said cavity having lateral dimensions representative of the lateral dimensions of a packaged component to be placed in said cavity;
a packaged component placed in one of said at least one cavity such that one surface of said packaged component is approximately co-planar with the top surface of said substrate; and
an electrically conductive layer formed over the top surface of said substrate and the approximately co-planar one surface of said packaged component.

39. Structure as in claim 38 having the characteristic that when said thermo-plastic or thermo-set plastic is heated and softens, the thermo-plastic or thermo-set plastic will flow around and adherently contact the packaged component to form plastic material in any cavity that may exist between the sides of the packaged component and the sides of the cavity in which the packaged component is placed thereby to adherently hold the packaged component in the cavity.

40. The method of fabricating a structure containing a plurality of packaged components which comprises:
placing a plurality of packaged components in a template, each packaged component having one surface upon which has been formed a plurality of electrically conductive lands, said surface containing said electrically conductive lands of each packaged component being directly adjacent said template;
placing said template adjacent a substrate of heat-softenable material such that the surface of each packaged component opposite the surface of each packaged component containing the electrically conductive lands is in contact with said substrate;
heating said substrate so as to allow each packaged component to adhere to said substrate;
removing said template and placing adjacent the surfaces of said packaged components containing said electrically conductive lands;
a planarizing plate;
heating said substrate so as to soften the material of said substrate; and
pressing said packaged components into the softened material of said substrate until the top surfaces of each of the packaged components into the softened material of said substrate until the top surfaces of each of the packaged components containing said electrically conductive lands are approximately coplanar with the top surface of said substrate.

41. The method of claim 40 including:
cooling said substrate thereby to allow the material of said substrate to harden and thus firmly imbed the packaged components in said substrate.

42. The method of claim 41 wherein said planarizing plate has a coating of material formed on the surface of said planarizing plate in contact with said packaged components to allow said planarizing plate to be easily removed from contact with said packaged components.

43. The method of fabricating a monolithic integrated structure containing a plurality of packaged components which comprises:
placing the plurality of packaged components adjacent a planarizing plate;
causing said packaged components to attach to said planarizing plate;
placing said planarizing plate with said packaged components attached thereto into an injection mold; and
injecting plastic material into said injection mold such that said plastic material surrounds each of said packaged components thereby to form an integrated structure holding each of said packaged components in fixed relationship to each other removing the molded structure from said mold.

44. The method of claim 43 wherein each of said packaged components has a plurality of electrically conductive lands formed on one surface thereof directly adjacent the planarizing plate.

45. The method of claim 44 including:
removing the injection molded structure from the injection mold;
removing the planarizing plate from the injection molded structure; and
forming an electrically conductive layer of material over the conductive lands and on the exposed surfaces of said packaged components and the top surface of said plastic material formed by injection molding.

46. The method of claim 45 including patterning said conductive layer into an electrically conductive interconnect so as to form said packaged components into a desired electrical circuit.

47. The method of fabricating a monolithic integrated structure containing one or more packaged components, which comprises:
providing a substrate;
picking one or more package components from a source of such package components and placing each of said one or more package components in a corresponding location on such substrate such that each such package component so placed is properly oriented in accordance with a planned orientation;
causing each such packaged component to be adherently held in position on such substrate.

48. The method of claim 47 including:
heating such substrate so as to soften the material of such substrate;
piercing each of said package components into the softened material of such substrate such that the top surface of each of said package components is visible but substantially coplanar with the top surface of said substrate; and
allowing the substrate to cool, thereby to solidly embed each of said packaged components in said cooled substrate.

49. The method of claim 48 including:
forming a layer of conductive material over the top surfaces of each of said packaged components and over the top surface of said substrate; and
patterning said conductor material into a selective electrically conductive interconnect pattern, thereby to interconnect said packaged components into a desired electrical circuit.

50. The method of fabricating a monolithic integrated structure containing one or more packaged components which comprises:
providing a substrate having a top surface thereon;
providing a template with openings in one surface thereof for receipt of one or more packaged components;
picking one or more packaged components from a source of such packaged components and placing each of said one or more packaged components in a corresponding opening in said template such that each said packaged component so placed is properly oriented in accordance with a planned orientation; and
placing said template adjacent said substrate such that the one or more packaged components in said template are placed in corresponding locations on said substrate.

51. The method of claim 50 including:
applying adhesive to the top surface of said substrate; and
pressing the one or more packaged components held by said template against said adhesive thereby to cause said one or more packaged components to be held in the proper orientation on the top surface of said substrate.

52. The method of claim 50 including:
heating said substrate such that said top surface becomes tacky; and
pressing the one or more package components held by said template against said tacky top surface thereby to cause said one or more packaged components to be held in the proper orientation on said top surface.

53. The method of claim 51 including:
removing said template from said substrate while leaving the one or more packaged components in proper location on said substrate.

54. The method of fabricating a monolithic integrated structure containing one or more packaged components which comprises:
providing a substrate having a top surface;
providing one or more cavities in said substrate, said one or more cavities opening to said top surface;
providing a source of one or more packaged components;
picking and placing selected ones of said one or more packaged components from said source into corresponding ones of said one or more cavities; and
causing said one or more packaged components to be firmly held in said one or more cavities.

55. The method of claim 54 including:
placing an adhesive on the bottom surfaces of said one or more cavities so as to hold the corresponding one or more packaged components in said cavities.

56. The method of claim 55 including:
placing each of said one or more packaged components in said one or more cavities such that electrically conductive lands on a surface of each of said one or more packaged components are visible along with the top surface of said substrate.

57. The method of claim 56 including:
providing one or more cavities in said substrate of such a depth that the one or more packaged components placed in said one or more cavities each have a visible surface approximately coplanar with the top surface of said substrate.

58. The method of claim 57 wherein each visible surface of said one or more packaged components includes thereon a plurality of electrically conductive lands for making electrical contact with the electrical component within the corresponding packaged component, and the method includes:
forming an electrically conductive layer on the top surface of said substrate, on the visible surface or surfaces of the one or more packaged components and on the electrically conductive lands on each of said visible surfaces; and
patterning said electrically conductive layer into an electrically conductive interconnect structure to interconnect the one or more packaged components to form a desired electrical circuit.

59. Structure as in claim 1 wherein said substrate comprises a plastic including fibers selected from the group consisting of glass, fiber glass, and aramid materials.

60. Structure as in claim 1 wherein said substrate comprises a metal stamped to form said at least one cavity.

61. Structure as in claim 1 wherein said substrate comprises a prepreg laminate material.

62. Structure as in claim 1 wherein said substrate comprises a ceramic.

63. Structure as in claim 1 wherein said substrate comprises a prepreg laminate material molded to form said at least one cavity in said substrate.
